(19) United States
(12) Patent Application Publication
(10) Pub. No.: US 2026/0202145 A1
(43) Pub. Date: Jul. 16, 2026

(54) COOLING ELEMENT AND METHOD FOR MANUFACTURING A COOLING ELEMENT

(71) Applicant: Infineon Technologies Austria AG, Villach (AT)

(72) Inventors: Uwe KIRCHNER, Witra (AT); Klaus SOBE, Rosegg (AT); Michael FÜGL, Neumarkt (DE); Anton MAUDER, Kolbermoor (DE); Julian TREU, München (DE)

(21) Appl. No.: 19/410,721

(22) Filed: Dec. 5, 2025

(30) Foreign Application Priority Data
Jan. 10, 2025 (DE) 102025100705.5

(51) Int. Cl. F28F 3/12; F28D 21/00; F28F 3/08; F28F 21/06; F28F 21/08

(52) U.S. Cl. CPC F28F 3/12; F28F 3/08; F28F 21/06; F28F 21/08; F28D 2021/0028; F28F 2255/00

(57) ABSTRACT

A cooling element for cooling of an electric device is provided. The cooling element includes a first plate having a first surface, a second plate having a first surface and a second surface opposite to the first surface, wherein the second surface is configured to be attached to the electric device, wherein the first plate and the second plate are attached to one another facing their respective first surface, wherein a first structure is arranged between the first plate and the second plate such that a channel is formed between the first plate and the second plate, and two liquid connectors in liquid communication with the channel for connecting the channel to a cooling circuit.

### CROSS-REFERENCE TO RELATED APPLICATION

This application claims priority to Germany Patent Application No. 102025100705.5 filed on Jan. 10, 2025, the content of which is incorporated by reference herein in its entirety.

### TECHNICAL FIELD

The present disclosure relates to a cooling element for cooling of an electrical device using a liquid, and a method for manufacturing such cooling element.

### BACKGROUND

Many electrical devices, in particular power semiconductor devices, generate heat during operation. This may cause heating up of the devices and if the heat is not removed by sufficient cooling, the devices may reach a critical temperature at which they might fail or may even catch fire. This problem becomes more severe with increasing power densities, since a thermal mass and/or a space for cooling of the device is reduced.

Conventional electric devices are cooled by convection of a cooling fluid, such as air. By attaching a heatsink to the respective device, an area for transferring heat from the device to the cooling fluid may be increased. Other conventional approaches employ liquid as cooling medium, which can have the advantage that the liquid can take up much more heat compared to a gaseous cooling fluid. Thus, a cooling liquid may remove more heat from the respective device.

However, conventional cooling solutions using liquid as cooling medium are complex to properly set up, including the development of individually adapted heatsinks and sealed cooling channels and tube connections to allow pumping of the liquid through the cooling circuit. In addition, conventional solutions are expensive, require a lot of space and are not easily adapted in case of a layout change of an electrical system.

It is one object of the present disclosure to provide an improved cooling element for cooling of an electric device using a liquid, and a corresponding method for manufacturing such cooling element.

### SUMMARY

According to a first aspect, a cooling element for cooling of an electric device is provided. The cooling element includes a first plate having a first surface, a second plate having a first surface and a second surface opposite to the first surface, wherein the second surface is configured to be attached to the electric device, wherein the first plate and the second plate are attached to one another facing their respective first surface, wherein a first structure is arranged between the first plate and the second plate such that a channel is formed between the first plate and the second plate, and two liquid connectors in liquid communication with the channel for connecting the channel to a cooling circuit.

According to a second aspect, a cooling element for cooling of an electric device is provided. The cooling element includes a plate having a first surface and a first structure formed thereon, a foil having a first surface and a second surface opposite to the first surface, wherein the second surface is configured to be attached to the electric device, wherein the plate and the foil are attached to one another facing their respective first surface such that the first structure is arranged between the plate and the foil such that a channel is formed between the plate and the foil, the channel being defined by the first structure, and two liquid connectors attached to the plate and in liquid communication with the channel for connecting the channel to a cooling circuit.

According to a third aspect, a method for manufacturing a cooling element for cooling of an electrical device is provided. The method includes the steps of providing a plate having a first surface and a second surface opposite to the first surface and including a first structure extending from the first surface, the first structure including a periodic arrangement of a basic cell structure, each basic cell structure including at least a cavity surrounded by walls, such that a plurality of cavities separated by intermediate walls are formed at the first surface, selectively removing at least one intermediate wall, such that the neighboring cavities are connected and form a flow path, providing a cover element having a first surface and a second surface opposite to the first surface, attaching the cover element to the plate such that their respective first surfaces are facing each other and the first structure is arranged between the plate and the cover element, and such that the flow path forms a channel configured to be streamed through by a cooling liquid, and attaching at least two connectors to the plate and/or the cover element and in liquid communication with the channel for connecting the channel to a cooling circuit.

According to a fourth aspect, a cooling element for cooling of at least two power semiconductor devices is provided. The cooling element includes a first plate configured to be attached to a first power semiconductor device, a second plate configured to be attached to a second power semiconductor device, an intermediate element including a frame, a liquid-guiding structure, a liquid inlet and a liquid outlet arranged in the frame, wherein the first plate is attached to a first side of the intermediate element and the second plate is attached to a second side of intermediate element such that a cavity is formed between the first plate, the second plate and the frame, wherein the liquid-guiding structure is arranged in the cavity and forms a channel that is in liquid communication with the liquid inlet and the liquid outlet, such that a cooling liquid can flow through the channel.

According to a fifth aspect, a method for manufacturing a cooling element for cooling of a power semiconductor device is provided. The method includes the steps of providing a first plate having a first surface, providing a second plate having a first surface and a second surface opposite to the first surface, wherein the second surface is configured to be attached to the power semiconductor device, providing a first structure configured for defining a flow path, joining the first plate and the second plate such that their respective first surface are facing each other, wherein the first structure is arranged between the first plate and the second plate such that a channel is formed between the first plate and the second plate, and attaching at least two connectors to the first plate and/or the second plate and in liquid communication with the channel for connecting the channel to a cooling circuit.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a vertical cross section of a first example of a cooling element.

FIGS. 2A and 2B each illustrate a horizontal section of a respective second example of a cooling element.

FIG. 3 illustrates an isometric view of a third example of a cooling element.

FIG. 4 illustrates a further isometric view of the third example of a cooling element.

FIG. 5 illustrates a vertical cross section of a fourth example of a cooling element.

FIG. 6 illustrates a vertical cross section of a fifth example of a cooling element.

FIG. 7 illustrates a top view of sixth example of a cooling element.

FIG. 8 illustrates a top view of a first example plate of a cooling element before processing to provide a flow path.

FIG. 9 illustrates a top view of the first example plate of a cooling element after processing to provide a flow path.

FIG. 10 illustrates a schematic cross section of a multilayer structure.

FIG. 11 illustrates a schematic block diagram of a first example method for manufacturing a cooling element.

FIG. 12 illustrates a schematic block diagram of a second example method for manufacturing a cooling element.

FIG. 13 illustrates a schematic block diagram of a system including a cooling circuit and a cooling element.

### DETAILED DESCRIPTION

The examples described herein provide a cooling element configured for cooling of an attached electric device, such as transformer coils, resistors, capacitors, semiconductor devices or the like, using liquid cooling. To this end, the cooling element provides a structure integrating a channel for the cooling liquid, and has liquid connectors in communication with the channel that allow the channel to be connected to a cooling circuit. By pumping cooling liquid through the channel, heat generated by the electric device attached to the cooling element may be more effectively removed from the electric device as compared to air cooling, such that the device can be operated in operating states with higher power dissipation without risk of thermal destruction.

The example cooling elements described may be integrated into a cooling circuit of a larger electric system, such as power converters and inverters, and used for cooling certain electric devices of the electric system. Here, integration into the cooling circuit may mean, for example, that the cooling element is connected or attached to the cooling circuit using suitable tubes that are plugged into the provided liquid connectors of the cooling element. When a pressure difference is present between the liquid connectors, cooling liquid will flow through the cooling channel. A cooling rate may depend on a flow rate of the cooling liquid, a temperature difference between the cooling liquid and the electric device, and a thermal impedance of the heat conduction path between the electric device and the channel, for example. Other factors may influence the cooling rate further.

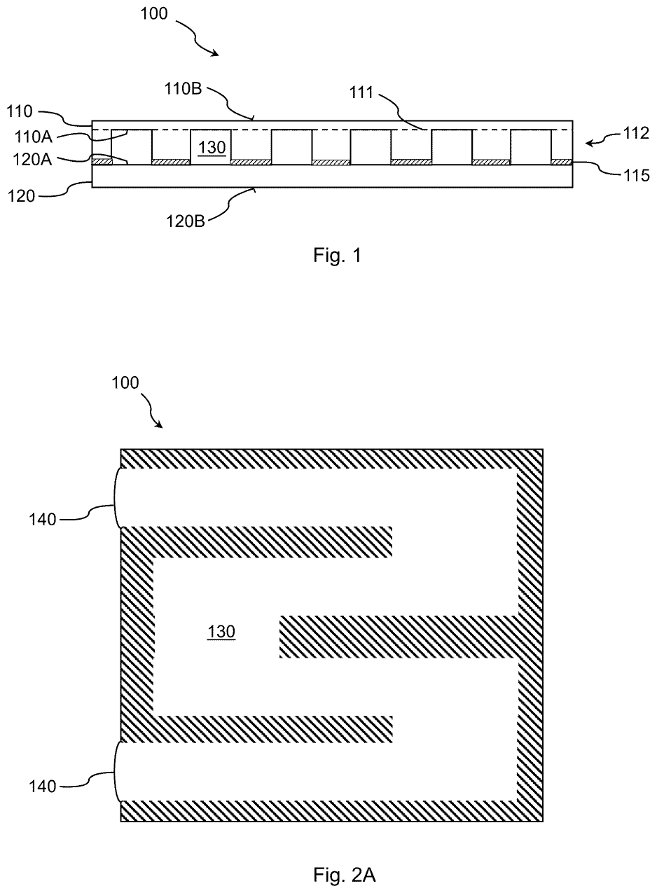

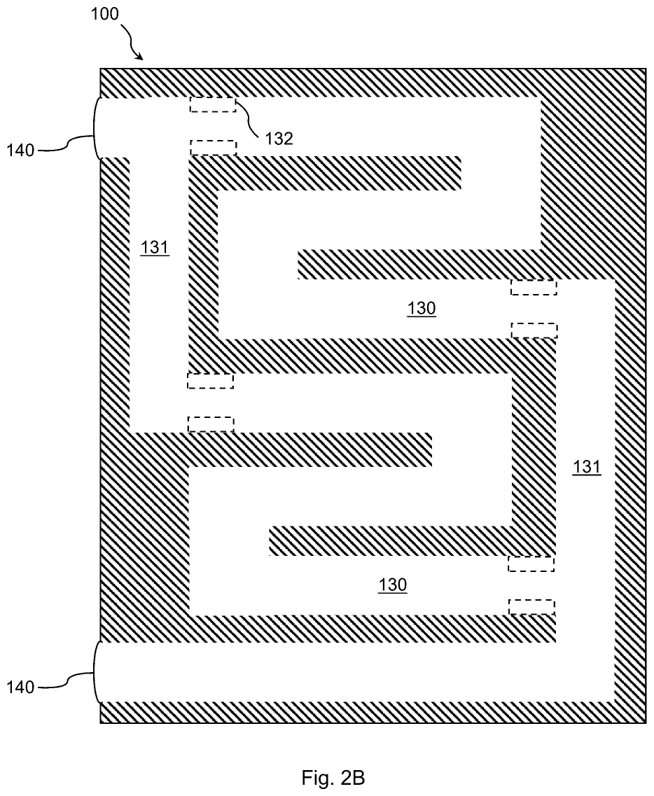

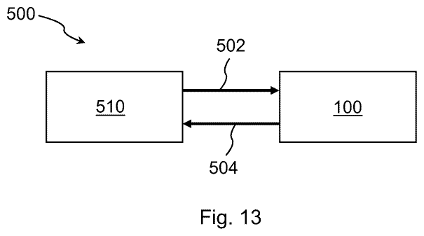

FIG. 1 shows a cross section of a first implementation of a cooling element 100 for cooling of an electric device according to the present disclosure. The cooling element 100 comprises a first plate 110 having a first surface 110A, a second plate 120 having a first surface 120A and a second surface 120B opposite to the first surface 120A, wherein the second surface 120B is configured to be attached to the electric device. The second plate 120 may comprise at least one cooling region (not shown) at the second surface 120B, wherein the cooling region is configured to transfer heat from an electric device in thermal contact with the cooling region to the second surface 120B, such that a cooling liquid flowing at the second surface 120B during operation of the cooling element 100 may take up and therefore remove heat from the electric device. The first plate 110 and the second plate 120 are attached to one another facing their respective first surface 110A, 120A. A first structure 112 is arranged between the first plate 110 and the second plate 120 such that a channel 130 is formed between the first plate 110 and the second plate 120. For example, channel 130 is formed such that it is leak proof. Here, leak proof means that no liquid may leak from the channel 130 to an area outside of the cooling element 100. However, it may be possible that some of the cooling liquid penetrates from a first section of the channel 130 into a second, distant section of the channel 130 without flowing along the channel 130. In other words, a small portion of cooling liquid may pass between the first plate 110, the first structure 112 and the second plate 120 outside of the channel 130, but without leaking out from the cooling element 100. This portion may be e. g. smaller than 1% or smaller than 10% of the liquid flowing through the corresponding channel 130. At a lateral end of the cooling element 100, the first structure 112 shall be configured to seal the cooling element 100 and avoid any liquid flow outside of specially configured connecting elements. All cooling liquid is provided to and ejected from the cooling element 100 via liquid connectors 140. For example, the channel 130 may be defined by the first structure 112. Two liquid connectors 140 (see FIGS. 2A, 2B, for example) are provided in liquid communication with the channel 130, so that channel 130 can be connected to a cooling circuit 510 (see FIG. 13). “In liquid communication” may mean that a liquid can be provided to or discharged from the channel via the liquid connectors.

FIG. 13 illustrates a schematic block diagram of a system 500 including a cooling circuit 510 and a cooling element 100, for example the cooling element shown in any of FIG. 1-7. The cooling circuit 510 may include at least one of a pump, radiator, a fan, a compressor, a thermoelectric element, or the like. The cooling circuit 510 is configured for circulating cooling liquid, for example through the channel 130 of connected cooling element 100. In addition, the cooling circuit 510 is configured for cooling down cooling liquid that comes from the cooling element 100 with an increased temperature. For example, the cooling circuit 510 and the cooling element are connected via tube or pipe connections. Here, tube 502 Is used for providing cooling liquid to the cooling element and tube 504 is used for returning the cooling liquid after passing through the cooling element 100. In other configurations, more than one cooling element 100 may be present. In this case, the cooling elements may be connected in series (e.g., daisy-chained) with respect to the cooling circuit 510 and/or may be connected in parallel.

FIG. 2A illustrates a top view of a second example of a cooling element 100, wherein the second plate 120 is on top of the cooling element 100 in this view. The cooling element 100 of FIG. 2A may have the same features as the cooling element described referring to FIG. 1. In FIG. 2A, the dashed lines are used to indicate the first structure 112, which is arranged below the second plate 120. Based on the geometry of the first structure 112 the channel 130 is formed. In this example, the channel 130 has a meander shape. Two connectors 140 are attached to the cooling element 100 to provide access to the channel 130 from an external cooling circuit (not shown). Each one of the connectors 140 may be provided in form of a plug or a socket. The connectors may be specifically configured to be plugged into a corresponding socket or to receive a corresponding plug to provide for a tight and sealed connection of the channel 130 to the external cooling circuit. In this example the connectors 140 are arranged in a side wall of the cooling element 100 (e.g., perpendicular to an extension plane of the first plate 110 and second plate 120), but other arrangements are also possible. Furthermore, more than two connectors 140 may be provided to provide access to the channel 130. Also, the different connectors 140 may have a different shape and/or different size.

In one or more implementations, the first structure 112 may have a geometry such that more than one channel 130, e.g., two channels, are formed (not shown). The two or more channels may be separate to each other. In this case, for each one of a plurality of channels a respective set of at least two connectors 140 (e.g., at least one inlet and one outlet) may be provided. Alternatively, or additionally, the more than one channels may have a common section. Furthermore, the two connectors 140 may be in liquid communication with at least two channels of the more than one channels 130. Such example is illustrated in FIG. 2B. Here, the two connectors 140 connect to a respective common channel section 131, which provides access to two separate channels 130. The two separate channels 130 are thus in a parallel arrangement having regard to liquid flow. Inside of one or more channels 130, optional flow limiting elements 132 may be provided configured to control a flow rate in the respective channel 130. For example, the flow limiting elements 132 may be formed at one or both transitions from the common channel section 131 to the respective channel 130 or may be formed inside the channel 130.

In one or more implementations of the cooling element 100, the first structure 112 is integral with the first plate 110 and extends from the first surface 110A of the first plate 110, as is shown in FIG. 1. Here, “integral” means that the first plate 110 and the first structure 112 are a monolithic body. For example, the first plate 110 including the first structure 112 may be formed by injection molding and/or using additive methods (e.g., 3D printing) and/or using machining (e.g., milling, drilling, turning, chipping, cutting etc.). Therefore, connecting the second plate 120 to the first structure 112 may be also understood as connecting the second plate 120 to the first plate 110.

In one or more implementations of the cooling element 100, the first plate 110 and the second plate 120 extend over the first structure 112 and are joined directly at the edge of the cooling element 100, without the first structure 112 intervening. For example, the first structure 112 is slightly smaller (e.g., in the range of several millimeters up to several centimeters at each lateral edge) than both the first plate 110 and the second plate 120. At least one of the first plate 110 and the second plate 120 may be bend towards the other plate to provide a direct contact line at a circumferential edge of the cooling element 100. This may have the advantage that only the circumferential edge of the cooling element has to be implemented in a leak proof manner, while the connection in other attachment areas (e.g., where the first structure 112A for forming the channel 130 is provided) may be implemented in a more simple way, and thus cheaper.

In one or more implementations, the first plate 110 and the first structure 112 may be provided as separate elements and joined by welding, glueing or molding, for example. For example, the dashed line 111 in FIG. 1 indicates the joining between the first plate 110 and the first structure 112.

In one or more implementations of the cooling element 100 the first plate 110 and the second plate 120 are attached to each other using welding, glueing or molding, for example.

In one or more implementations of the cooling element 100 a welding seam between the first plate 110 and the second plate 120 is formed exclusively from material of the first plate 110 and/or the second plate 120. In these implementations, the welding is performed without providing a further material, such as a welding material or a filler material. In other words, it is the material of at least one of the first plate 110 and the second plate 120 that is subjected to the welding process. It is noted that this does not exclude the use of a welding support material, such as a shielding gas, that does not become part of the welding seam, during the welding process. Here, for example, at least one of the first plate 110 and the second plate 120 comprises a weldable material. The weldable material may comprise a plastic material, in particular a thermoplastic material, and/or a metal material.

The welding process may include heating of the arrangement of the first plate 110 and the second plate 120, including the first structure 112 in between, and applying a pressure such that the plates are pressed against each other. The heating may be performed globally (e.g., including the complete arrangement) and/or locally (e.g., only at selected contact areas between the plates).

In one or more implementations of the cooling element 100 the first plate 110 and/or the second plate 120 comprises a functionalized surface region 115 that is specifically functionalized to provide an attachment area for attachment of the respective other one of the first plate 110 or the second plate 120. The functionalized surface region 115 may be functionalized by chemical, physical and/or mechanical process. Chemical functionalization may include a surface treatment using chemical agents resulting in a change of the surface structure, and/or may include coating the surface region with a functional agent, such as a polymer. Physical functionalization may include a surface treatment using a plasma and/or irradiating the surface with electromagnetic radiation (e.g., laser beam) or particles (e.g., electrons or sputtering with atoms/molecules). Mechanical functionalization may include a sand blasting process, a grinding process, a polishing process or the like. Of course, the different functionalization processes may be combined. The functionalization may be selectively applied to the respective surface to provide the functionalized surface region 115. For example, the functionalized surface region 115 may be limited to contact areas between the first plate 110 and the second plate 120. The functionalization may be provided on only the first plate 110, only the second plate 120, or on both the first plate 110 and the second plate 120. In addition, the functionalization may be provided on the first plate 110 in a first region and on the second plate 120 in a second region. The functionalization of the first plate 110 may be different to the functionalization of the second plate 120.

In one or more implementations of the cooling element 100 at least one of the first plate 110 and the second plate 120 is made substantially of a plastic material or a composite material and/or is formed in an injection molding process. Here, “made substantially of” means that the body of the respective plate is formed from the material, but the respective plate may include other elements, such as the functionalized surface region 115, and/or elements that may be employed for fixing the respective plate or the cooling element to other elements, and/or elements that may provide for mechanical support or the like. For example, a socket or a pin of a material different to the remainder of the respective plate may be provided.

In one or more implementations of the cooling element 100 the second plate 120 is formed from a multilayer substrate, in particular an insulated metal substrate (IMS), direct copper bonded (DCB) substrate, active metal brazed (AMB) substrate or a printed circuit board (PCB).

Here, multilayer substrate means that the substrate includes a plurality of layers. The different layers may be of a same material or of a different material. For example, the multilayer substrate may be a laminate of a plurality of layers.

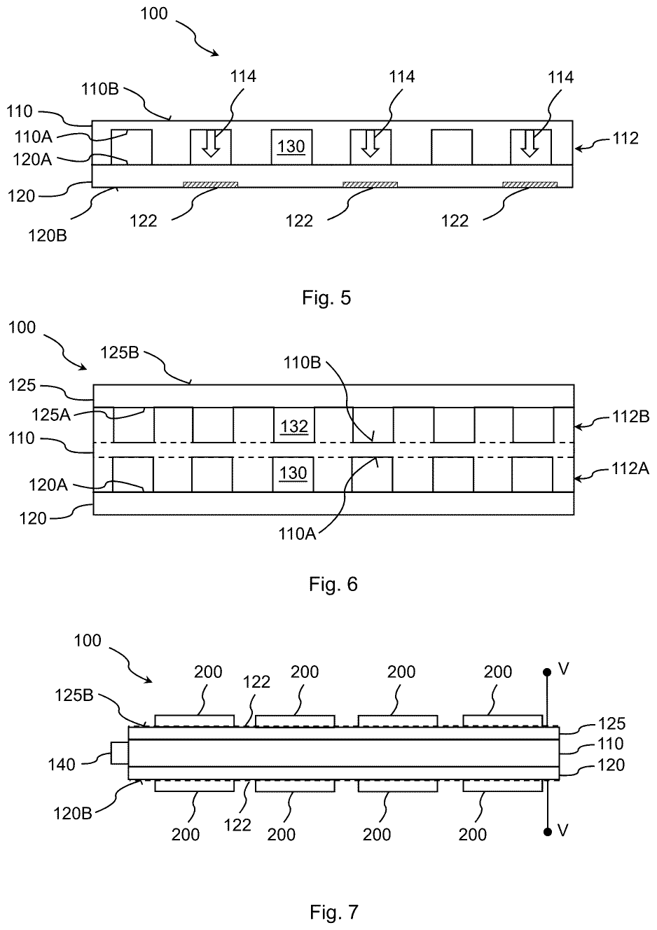

In one or more implementations of the cooling element 100 the second plate 120 comprises a metal layer 122 (see FIG. 5) at its second surface 120B configured to conduct an electrical signal. The electrical signal may include at least one of a control signal, a measurement signal, or a load current.

In one example, the metal layer 122 is configured for conducting a load current that is controlled by the electric device 200 (see FIG. 4 or 7). In this example, the electric device 200 may be implemented as a power semiconductor transistor that is controlled according to a control signal provided by a controller to provide a load current to an electrical load. The metal layer 122 may be electrically connected to a positive or negative power supply node, for example a DC+ or DC− bus.

In one or more implementations the metal layer 122 is a structured layer having a plurality of sections. The different sections may be separate to each other. For example, the different section may be electrically isolated with respect to each other. In this case, the different sections may be used to conduct different electrical signals. In one example, a first section may be used to conduct a load current and a second section may be used to conduct a control signal or the like. In a further example, a first section may be used to conduct a first load current and a second section may be used to conduct a second load current. In a further example, the structured metal layer may include one or more conductive traces that may be used to route one or more electrical signals. In further implementations the different sections may be electrically coupled with each other, the coupling being implemented such that a specific impedance between the different section is provided. For example, the coupling may provide for a specific resistance value, a specific capacitive coupling or a specific magnetic coupling.

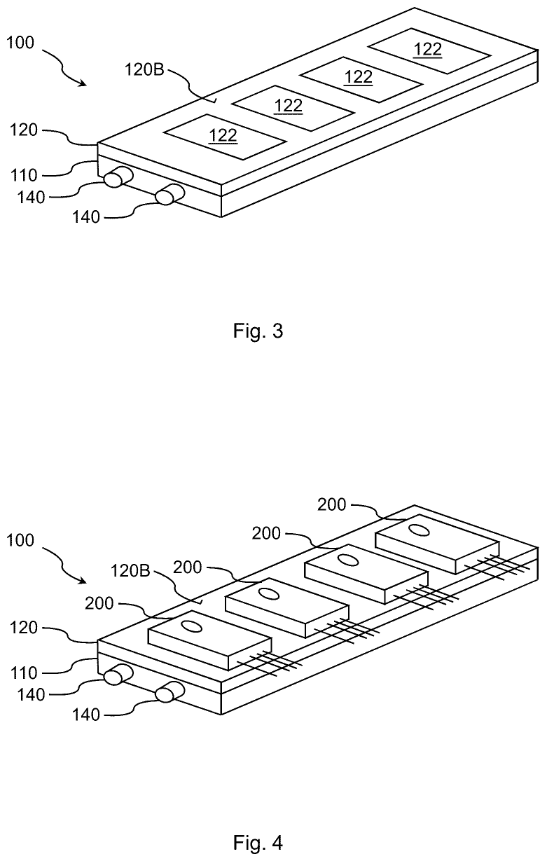

FIG. 3 illustrates an isometric view of a third example of a cooling element 100. In this example, the second surface 120B of the second plate 120 includes a metal layer 122 that is structured into four separate sections. Each one of the sections of the metal layer 122 may be configured for conducting a load current or a different electrical signal. Here, the four sections of the metal layer 122 are configured such that they may serve as attachment areas for attaching a respective electric device 200 to be cooled. In particular, as shown in FIG. 4, the electric devices 200 are implemented as power semiconductor switches in a package, such as a TO-247 package. This is just an example and semiconductor devices packaged in other packages, in particular packages that are conventionally used in the industry, may be used. The power semiconductor devices 200 may be soldered or sintered with their backside to the respective section of the metal layer 122 provided at the second surface 120B of the second plate 120. It should be noted that other means for attaching the power semiconductor devices 200 may also be used, such as screwing or clamping or the like.

FIG. 5 illustrates a cross section of a fourth example of a cooling element 100. The cooling element 100 of FIG. 5 may have the same features as described referring to FIG. 1. In addition, the first structure 112 includes additional elements 114 that extend from the first surface 110A at positions where the channel 130 is formed when the second plate 120 is attached. The additional elements 114 may be provided selectively in selected positions and may act as turbulators causing a turbulence in the cooling liquid flowing through the channel 130. This may increase the heat transfer to the cooling liquid. In addition, the second plate 120 includes at its second surface 120B the metal layer 122. In this example, the metal layer 122 includes three sections, each section configured for attaching the electric device 200 (e. g. a power semiconductor or other electric device that needs to be cooled). It is noted that the sections of the structured metal layer 122 are arranged corresponding to the turbulators 114 in the channel 130 in this example. The structured metal layer 122 may further have a relatively high heat conductivity (e.g., higher than that of the material of the second plate 120), such that a heat transfer from the electric device 200 to the cooling liquid flowing in the channel 130 may be improved.

In one or more implementations of the cooling element 100 the second plate 120 includes an isolating material arranged to provide for electric isolation between the first surface 120A and the second surface 120B of the second plate 120.

This has the advantage that a voltage that may be applied to a metal layer 122 at the second surface 120B of the second plate 120 is isolated from the cooling liquid, and thus also from the cooling circuit. For example, the isolating material may be a polymer, plastic, fiber, ceramic or glass material. In one or more implementations, the isolating material is formed as a layer of the second plate 120.

In one or more implementations, an electrical device may be arranged on one of the first surface 120A of the second plate 120 and/or on the second surface 120B of the second plate 120 and/or integrated in the second plate 120. For example, the electrical device may be a resistor, a capacitor, an inductor, a diode, a transistor, a transformer an integrated electronic circuit or any kind of sensing element, for example. In one example the electrical device may be a temperature sensor arranged on the first surface 120A of the second plate 120 and configured to provide a temperature signal indicative of a temperature of the cooling liquid in the channel 130. For this, the temperature sensor may be arranged on the second surface 120A so as to reach into the channel 130. The temperature sensor may be connected to connection terminals arranged at the second surface 120B by conductive traces (e.g., vias) reaching through the body of the second plate 120. In one example, the electrical device is integrated in the second plate 120, which means that it is arranged between the first surface 120A and the second surface 120B. The electrical device may be connected to terminals at the second surface 120B by conductive traces reaching through the body of the second plate 120.

FIG. 6 illustrates a cross section of a fifth example of a cooling element 100. In this implementation, a third plate 125 having a first surface 125A and a second surface 125B opposite to the first surface 125A, wherein the second surface 125B is configured to be attached to the electric device 200. The third plate 125 is attached to the first plate 110 opposite to the second plate 120 wherein a second structure 112B is arranged between the first plate 110 and the third plate 125 such that a further channel 132 is provided between the first plate 110 and the third plate 125.

In this example, the first plate 110 may have the first structure 112A at its first surface 110A and the second structure 112B at its second surface 110B. The first structure 112A and/or the second structure 112B may be integral with the first plate 110. The further channel 132 is defined by the second structure 112B. Although the channel 130 and the further channel 132 have an identical shape in this illustration, this is not required. Instead, the channel 130 and the further channel 132 may have different shapes and/or geometries and may be specifically adapted based on the electric device 200 to be cooled at the respective side of the cooling element 100. The first plate 110 and/or the first structure 112A and/or the second structure 112B may be realized in the same and/or a single manufacturing process. For example, the first plate 110 including the first structure 110A and the second structure 112B may be formed in a single molding process. Alternatively, the first structure112A and/or the second structure 112B may be formed as separate elements and then joined to the first plate 110.

FIG. 7 illustrates a top view of sixth example of a cooling element 100. In this example, the cooling element 100 may have a structure similar to the one shown in FIG. 6, with the first plate 110, the second plate 120 and the third plate 125 forming a sandwich structure with a channel 130 and a further channel 132 for cooling of attached electric devices 200. In this example, the electric devices 200 are power semiconductor transistors, but other implementations are also possible. In this example, the respective second surface 120B, 125B of the second plate 120 and the third plate 125 includes a metal layer 122. As schematically indicated, the metal layer 122 may be connected to a bus voltage (indicated as “V” in FIG. 7) during operation of the power semiconductor transistors 200. For example, the power semiconductor transistors 200 may be attached to the cooling element 100 with their drain contact electrically connected to the metal layer 122. In this case, the second plate 120 and the third plate 125 may preferably include an electrically isolating layer for isolating the metal layer 122 from the cooling liquid. Thus, the metal layer 122 forms a load node for each one of the power semiconductor transistors 200 and is configured for conducting a load current. This may simplify an electrical layout of a system using the power semiconductor transistors 200. As mentioned above, the metal layer 122 may also be structured and may be used for conducting additional and/other electrical signals.

It is noted that the number of devices 200 is variable, meaning that there may be more than eight or less than eight devices attached to the cooling element 100, and the number of devices 200 attached to the second plate 120 may differ from the number of devices 200 attached to the third plate 125. In addition, different types or different kinds of electric devices 200 may be attached at the respective side of the cooling element 100. As an example, different power semiconductor devices (e.g., transistors and/or diodes having different voltage classes and/or different technology) and/or different kinds of electric devices (e.g., inductors, capacitors, resistors, etc.) may be attached at either side of the cooling element 100.

In one or more implementations of the cooling element 100, two further liquid connectors (not shown) are provided in liquid communication with the further channel 132 for connecting the further channel 132 with the cooling circuit. Thus, cooling liquid may be provided to the further channel 132 separately from cooling liquid provided to the channel 130.

In one or more implementations of the cooling element 100, the two liquid connectors 140 are in liquid communication with the further channel 132. Thus, cooling liquid can be provided to both the channel 130 and the further channel 132 using only two liquid connectors 140.

In one or more implementations of the cooling element 100 the channel 130 and the further channel 132 are in liquid communication with each other. In further implementations, the channel 130 and the further channel 132 form a common channel in at least a section.

This means, for example, that the channel 130 and the further channel 132 may have a common liquid distribution part (for distributing cooling liquid provided through the connector 140 to cooling areas of the respective channel 130, 132) and/or a common liquid discharge part (for collecting the cooling liquid after it has passed the cooling areas of the respective channel 130, 132 and discharging it via the other connector 140).

In one or more implementations of the cooling element 100 the second plate 120 and/or the third plate 125 (if present) comprises second structures extending from its first surface 120A, 125A and into the channel 130, 132 (not shown). For example, the second structures may include elements to increase a surface area that is in contact with the cooling liquid and/or turbulator structures to enhance the heat transfer from the second plate 120 or third plate 125 to the cooling liquid flowing through the channel 130 or further channel 132.

In one or more implementations of the cooling element 100 the first plate 110 comprises additional elements extending from the first surface 110A and/or from the second surface 120B acting as turbulators to enhance a heat transfer from the second plate 120 or third plate 125 to the cooling liquid flowing through the channel 130 or further channel 132.

In one or more implementations of the cooling element 100 the first structure 112 comprises a plurality of basic cell structures 113 that are arranged in a grid on the first surface 110A of the first plate 110.

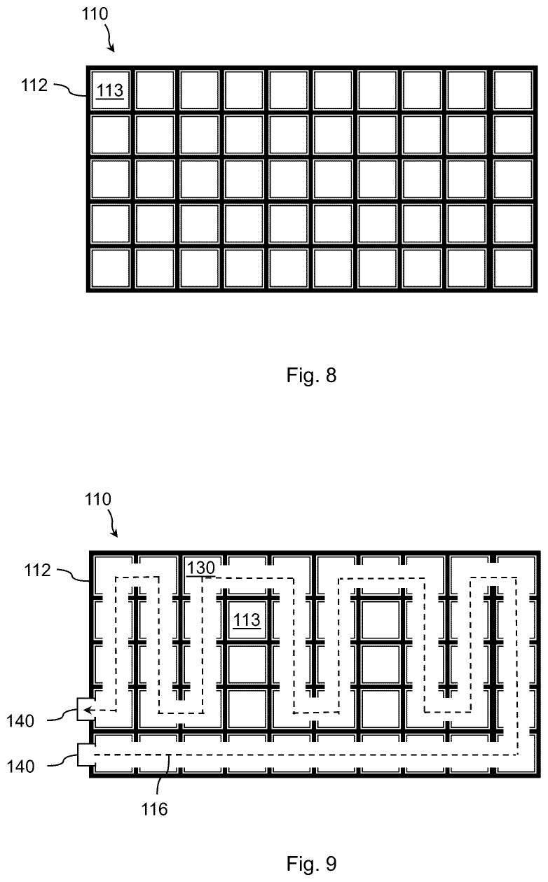

One example of such a first plate 110 is shown in FIG. 8. In this example, the first structure 112 includes a grid of 5 by 10 basic cell structures 113. The first plate as shown in FIG. 8 may be used as a starting point to define a channel 130, for example by selectively removing walls between adjoining basic cell structures 113. It is noted that other geometries of the basic cell structures are possible, such as triangular, rectangular, circular, hexagonal or any other suitable basic geometric form that can be used to fill the first surface of the first plate 110.

In one or more implementations of the cooling element 100 the first surface 110A of the first plate 110 is covered by a periodic arrangement of the basic cell structures 113, such that the first surface 110A is filled by cavities separated by intermediate walls, wherein the channel 130 is formed by adjoining cavities between which the intermediate walls are removed.

An example of such a first plate 110 is shown in FIG. 9. By joining cavities of the individual basic cell structures (e.g., by selectively removing a number of intermediate walls between neighboring cavities, such that the respective cavities are joined together) a flow path 116 is formed. In addition, liquid connectors 140 are attached to the first plate 110 at the two ends of the flow path 116. When forming the flow path 116 by removing the intermediate wall structures, some portion of the respective intermediate wall structures may be not removed intentionally so as to provide for a flow regulating and/or turbulator structure. When the second plate or a foil is attached on top of the first plate 110 the flow path 116 will form a channel 130.

In some implementations, two or more flow paths 116 may be formed in the first plate 110 (not shown). The two or more flow paths 116 may be connected to separate pairs of liquid connectors 140. Two or more flow paths may be in liquid communication with a same pair of liquid connectors 140, for example using a common section of the flow path. Some portion of the respective intermediate wall structures may be not removed intentionally so as to provide for a flow limiting element while at other parts, for example in the common sction, more wall structures may be removed to provide a larger cross section for the cooling liquid.

The first plate 110 as shown in FIG. 8 may be considered as a template that may be used to define a channel for the cooling liquid in a simple manner. In particular, if the required number of separate cooling elements 100 to set up a cooling system for a specific electric system is low, the first plate 110 may be an economic way that allows free customization of the channel geometry and does not require much material. Due to the basic cell structure 113 that may have a material filling ratio (e.g., the portion of the volume of a basic cell structure that is filled with material) of between 10%-50%, for example, the first plate 110 requires much less material to be manufactured compared with a solid plate.

In one or more implementations of the cooling element 100 at least one cavity is not connected to the channel 130 and is configured for receiving a fixing element for attaching the cooling element 100 to the electric device 200. Alternatively or additionally, the at least one cavity can be configured for receiving a fixing element for attaching the cooling element 100 to an external fixing structure, such as a frame or a housing. This is shown in FIG. 9, where a total of six cavities are not part of the flow path 116, and therefore not part of the channel 130.

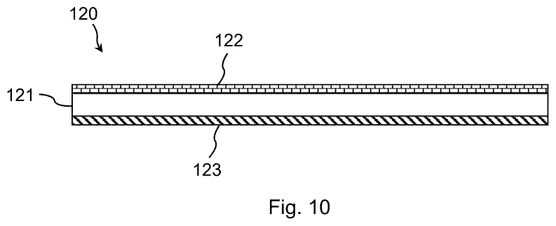

FIG. 10 illustrates a schematic cross section of a multilayer structure that may be used as second plate 120 or third plate 125 in a cooling element as described above, for example. In this example, the multilayer structure 120 includes a core element 121, a structured metal layer 122 on one side and an isolating material layer 123 on the other side. The core element 121 may be particularly used to provide mechanical integrity and stability to the structure. Preferably, the core element 121 has good thermal conduction properties. For example, the core element 121 has a thermal conductivity coefficient of greater than 10 W/(m·K). The structured metal layer 122 may be used for attaching electric devices to be cooled and for conducting electrical signal as described above. The multilayer structure 120 may be a laminate, for example.

According to a second aspect of the present disclosure, a cooling element 100 for cooling of an electric device 200 comprises a plate 110 having a first surface 110A and a first structure 112 formed thereon, a foil 120 having a first surface and a second surface opposite to the first surface, the second surface configured to be attached to the electric device 200, wherein the plate 110 and the foil 120 are attached to one another facing their respective first surface such that the first structure 112 is arranged between the plate 110 and the foil 120 such that a channel 130 is formed between the plate 110 and the foil 120, wherein the channel 130 is defined by the first structure 112, and two liquid connectors 140 are attached to the plate 110 and are in liquid communication with the channel 130 for connecting the cooling element 100 to a cooling circuit.

For example, the cooling element shown in FIG. 9 may be implemented as described by using a foil instead of a second plate 120. This may have the advantage of ease of manufacturing as well as a further cost reduction.

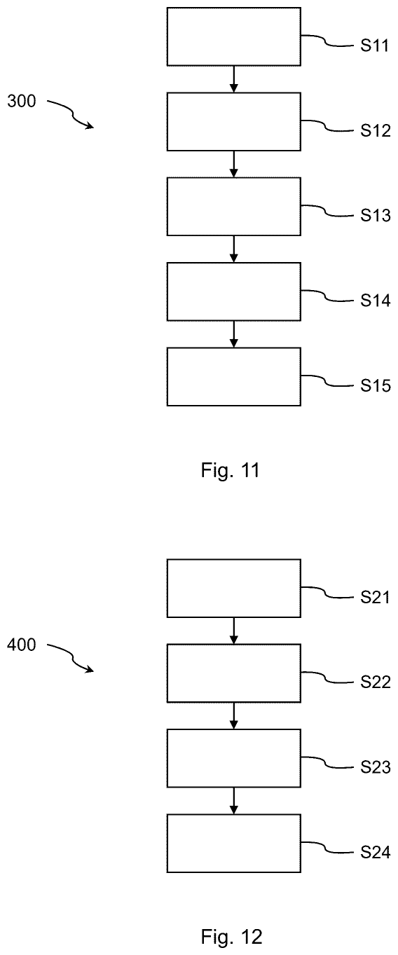

According to a third aspect, a method 300 for manufacturing a cooling element 100 for cooling of an electric device 200 is suggested. The method 300 is exemplified in FIG. 11 and comprises the following steps. In a first step S11, a plate 110 having a first surface and a second surface opposite to the first surface and comprising a first structure 112 extending from the first surface, the first structure 112 comprising a periodic arrangement of a basic cell structure 113, each basic cell structure including at least a cavity surrounded by walls, such that a plurality of cavities separated by intermediate walls is formed at the first surface 112, is provided. For example, the plate 110 may be in the form as shown in FIG. 8. The plate 110 may be formed by injection molding of a suitable material, for example. In a second step S12 at least one intermediate wall is selectively removed, such that the neighboring cavities are connected and form a flow path 116. The removing may be done by any suitable method, such as milling, chipping, drilling, turning, fusing etc. In a third step S13, a cover element having a first surface and a second surface opposite to the first surface is provided. The cover element may be a foil, for example, or may be a solid plate. In a fourth step S14 the cover element is attached to the plate 110 such that their respective first surfaces are facing each other and the first structure 112 is arranged between the plate 110 and the cover element, and such that the flow path 116 forms a channel 130 configured to be streamed through by a cooling liquid. The attaching may be done by a thermal treatment, such as laminating. In a fifth step S15, at least two connectors 140 are provided such that they are in liquid communication with the channel 130 for connecting the channel 130 to a cooling circuit. It is noted that in a simple form, the connectors 140 may be provided by simply drilling a hole through a side wall of the cooling element 100.

According to a further aspect of the present disclosure, a cooling element 100 for cooling of at least two power semiconductor devices 200 comprises a first plate 120 configured to be attached to a first power semiconductor device 200, a second plate 125 configured to be attached to a second power semiconductor device 200, an intermediate element 110 comprising at least a frame and at least a liquid-guiding structure, and a liquid inlet 140 and a liquid outlet 140 arranged in the frame, wherein the first plate 120 is attached to a first side of the intermediate element 110 and the second plate 125 is attached to a second side of the intermediate element 110 such that a cavity is formed between the first plate 120, the second plate 125 and the frame, wherein the liquid-guiding structure is arranged in the cavity and forms a channel 130 that is in liquid communication with the liquid inlet 140 and the liquid outlet 140, such that a cooling liquid can flow through the channel 130.

According to a further aspect of the present disclosure, a method 400 for manufacturing a cooling element 100 for cooling of an electric device 200 comprises the following steps. In a first step S21, a first plate 110 having a first surface 110A is provided. In a second step S22, a second plate 120 having a first surface 120A and a second surface 120B opposite to the first surface 120A is provided. The second surface 120B is configured to be attached to the electric device 200. In a third step S23 a first structure 112 configured for defining a flow path 116 is provided. The first structure 112 may be a separate element or may be provided on the first surface 110A of the first plate 110, for example by removing material or by depositing material. In a fourth step S24 the first plate 110 and the second plate 120 are joined such that their respective first surface 110A, 120A are facing each other, wherein the first structure 112 is arranged between the first plate 110 and the second plate 120 such that a channel 130 is formed between the first plate 110 and the second plate 120 as defined by the flow path 116. In a fifth step, at least two connectors 140 are provided that are in liquid communication with the channel 130 for connecting the channel 130 to a cooling circuit.

Although specific examples have been illustrated and described herein, it will be appreciated by those of ordinary skill in the art that a variety of alternate and/or equivalent implementations may be substituted for the specific examples shown and described without departing from the scope of the present implementation. This application is intended to cover any adaptations or variations of the specific examples discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

### ASPECTS

The following provides an overview of some Aspects of the present disclosure:
Aspect 1: A cooling element for cooling of an electric device, comprising: a first plate having a first surface; a second plate having a first surface and a second surface opposite to the first surface, wherein the second surface is configured to be attached to the electric device; the first plate and the second plate are attached to one another facing their respective first surface, wherein a first structure is arranged between the first plate and the second plate such that a channel is formed between the first plate and the second plate; and two liquid connectors in liquid communication with the channel for connecting the channel to a cooling circuit.
Aspect 2: The cooling element of Aspect 1, wherein the first structure is integral with the first plate and extends from the first surface of the first plate.
Aspect 3: The cooling element of any of Aspects 1-2, wherein the first plate and the second plate are attached to each other using welding.
Aspect 4: The cooling element of Aspect 3, wherein a welding seam is formed exclusively from material of the first plate and/or the second plate.
Aspect 5: The cooling element of any of Aspects 1-4, wherein the first plate and/or the second plate comprises a functionalized surface region that is specifically functionalized to provide an attachment area for attachment of a respective other one of the first plate or the second plate.
Aspect 6: The cooling element of any of Aspects 1-5, wherein at least one of the first plate and the second plate is made substantially of a plastic material or a composite material and/or is formed in an injection molding process.
Aspect 7: The cooling element of any of Aspects 1-6, wherein the second plate is formed from an insulated metal substrate or a direct copper bonded substrate, an active metal brazed substrate or a printed circuit board material.
Aspect 8: The cooling element of Aspect 7, wherein the second plate comprises a metal layer at its second surface configured to conduct an electrical signal.
Aspect 9: The cooling element of Aspect 8, wherein the metal layer is configured to conduct a load current that is controlled by the electric device.
Aspect 10: The cooling element of any of Aspects 1-9, wherein the second plate includes an isolating material arranged to provide for electric isolation between the first surface and the second surface of the second plate.
Aspect 11: The cooling element of any of Aspects 1-10, further comprising: a third plate having a first surface and a second surface opposite to the first surface, wherein the second surface is configured to be attached to the electric device, the third plate is attached to the first plate opposite to the second plate, wherein a second structure is arranged between the first plate and the third plate such that a further channel is formed between the first plate and the third plate.
Aspect 12: The cooling element of Aspect 11, further comprising: at least one further liquid connector in liquid communication with the further channel for connecting the further channel with the cooling circuit.
Aspect 13: The cooling element of Aspect 12, wherein the two liquid connectors are in liquid communication with the further channel.
Aspect 14: The cooling element of Aspect 13, wherein the channel and the further channel are in liquid communication with each other and/or form a common channel in at least a section.
Aspect 15: The cooling element of any of Aspects 1-14, wherein the second plate comprises second structures extending from its first surface and into the channel.
Aspect 16: The cooling element of any of Aspects 1-15, wherein the first structure comprises a plurality of basic cell structures that are arranged in a grid on the first surface of the first plate.
Aspect 17: The cooling element of Aspect 16, wherein the first surface of the first plate is covered by a periodic arrangement of the basic cell structures, such that the first surface is filled by cavities separated by intermediate walls, and wherein the channel is formed by adjoining cavities between which the intermediate walls are removed.
Aspect 18: The cooling element of Aspect 17, wherein at least one cavity is not connected to the channel and is configured for receiving a fixing element for attaching the cooling element to the electric device and/or to an external fixing structure.
Aspect 19: The cooling element of any of Aspects 1-18, further comprising: at least one power semiconductor device attached to the second surface of the second plate.
Aspect 20: The cooling element of Aspect 12, further comprising: at least a first power semiconductor device attached to the second surface of the second plate, and at least a second power semiconductor device attached to the second surface of the third plate.
Aspect 21: The cooling element of Aspect 20, wherein the first power semiconductor device is attached to the second plate by a first soldered bond or a first sintered bond, and/or wherein the second power semiconductor device is attached to the third plate by a second soldered bond or a second sintered bond.
Aspect 22: The cooling element of Aspect 19, wherein each power semiconductor device of the at least one power semiconductor device is provided in a respective TO-247semiconductor package.
Aspect 23: A cooling element for cooling of an electric device, comprising: a plate having a first surface and a first structure formed thereon; a foil having a first surface and a second surface opposite to the first surface, configured to be attached to the electric device at the second surface; the plate and the foil are attached to one another facing their respective first surface such that the first structure is arranged between the plate and the foil such that a channel is formed between the plate and the foil, wherein the channel is defined by the first structure; and two liquid connectors at the plate and in liquid communication with the channel for connecting the channel to a cooling circuit.
Aspect 24: A method for manufacturing a cooling element for cooling of an electrical device, comprising the steps of: providing a plate having a first surface and a second surface opposite to the first surface and comprising a first structure extending from the first surface, the first structure comprising a periodic arrangement of a basic cell structure, each basic cell structure including at least a cavity surrounded by walls, such that a plurality of cavities separated by intermediate walls are formed at the first surface, selectively removing at least one intermediate wall, such that neighboring cavities of the plurality of cavities are connected and form a flow path, providing a cover element having a first surface and a second surface opposite to the first surface, attaching the cover element to the plate such that their respective first surfaces are facing each other and the first structure is arranged between the plate and the cover element, and such that the flow path forms a channel configured to be streamed through by a cooling liquid, and providing at least two connectors in liquid communication with the channel for connecting the channel to a cooling circuit.
Aspect 25: A cooling element for cooling of at least two power semiconductor devices, comprising: a first plate configured to be attached to a first power semiconductor device; a second plate configured to be attached to a second power semiconductor device; an intermediate element comprising at least a frame and at least a liquid-guiding structure; a liquid inlet arranged in the frame; and a liquid outlet arranged in the frame, wherein the first plate is attached to a first side of the intermediate element and the second plate is attached to a second side of the intermediate element such that a cavity is formed between the first plate, the second plate and the frame, wherein the liquid-guiding structure is arranged in the cavity and forms a channel that is in liquid communication with the liquid inlet and the liquid outlet, such that a cooling liquid can flow through the channel.
Aspect 26: A method for manufacturing a cooling element for cooling of an electric device, comprising the steps of: providing a first plate having a first surface, providing a second plate having a first surface and a second surface opposite to the first surface, wherein the second surface is configured to be attached to the electric device, providing a first structure defining a flow path, joining the first plate and the second plate such that their respective first surfaces are facing each other, wherein the first structure is arranged between the first plate and the second plate such that a channel is formed between the first plate and the second plate and as defined by the flow path, and providing at least two connectors in liquid communication with the channel for connecting the channel to a cooling circuit.
Aspect 27: A system configured to perform one or more operations recited in one or more of Aspects 1-26.
Aspect 28: An apparatus comprising means for performing one or more operations recited in one or more of Aspects 1-26.

1. A cooling element for cooling of an electric device, comprising:
a first plate having a first surface;
a second plate having a first surface and a second surface opposite to the first surface, wherein the second surface is configured to be attached to the electric device;
the first plate and the second plate are attached to one another facing their respective first surface, wherein a first structure is arranged between the first plate and the second plate such that a channel is formed between the first plate and the second plate; and
two liquid connectors in liquid communication with the channel for connecting the channel to a cooling circuit.

2. The cooling element of claim 1, wherein the first structure is integral with the first plate and extends from the first surface of the first plate.

3. The cooling element of claim 1, wherein the first plate and the second plate are attached to each other using welding.

4. The cooling element of claim 3, wherein a welding seam is formed exclusively from material of the first plate and/or the second plate.

5. The cooling element of claim 1, wherein the first plate and/or the second plate comprises a functionalized surface region that is specifically functionalized to provide an attachment area for attachment of a respective other one of the first plate or the second plate.

6. The cooling element of claim 1, wherein at least one of the first plate and the second plate is made substantially of a plastic material or a composite material and/or is formed in an injection molding process.

7. The cooling element of claim 1, wherein the second plate is formed from an insulated metal substrate or a direct copper bonded substrate, an active metal brazed substrate or a printed circuit board material.

8. The cooling element of claim 7, wherein the second plate comprises a metal layer at its second surface configured to conduct an electrical signal.

9. The cooling element of claim 8, wherein the metal layer is configured to conduct a load current that is controlled by the electric device.

10. The cooling element of claim 1, wherein the second plate includes an isolating material arranged to provide for electric isolation between the first surface and the second surface of the second plate.

11. The cooling element of claim 1, further comprising:
a third plate having a first surface and a second surface opposite to the first surface, wherein the second surface is configured to be attached to the electric device,
the third plate is attached to the first plate opposite to the second plate, wherein a second structure is arranged between the first plate and the third plate such that a further channel is formed between the first plate and the third plate.

12. The cooling element of claim 11, further comprising:
at least one further liquid connector in liquid communication with the further channel for connecting the further channel with the cooling circuit.

13. The cooling element of claim 12, wherein the two liquid connectors are in liquid communication with the further channel.

14. The cooling element of claim 13, wherein the channel and the further channel are in liquid communication with each other and/or form a common channel in at least a section.

15. The cooling element of claim 1, wherein the second plate comprises second structures extending from its first surface and into the channel.

16. The cooling element of claim 1, wherein the first structure comprises a plurality of basic cell structures that are arranged in a grid on the first surface of the first plate.

17. The cooling element of claim 16, wherein the first surface of the first plate is covered by a periodic arrangement of the basic cell structures, such that the first surface is filled by cavities separated by intermediate walls, and
wherein the channel is formed by adjoining cavities between which the intermediate walls are removed.

18. The cooling element of claim 17, wherein at least one cavity is not connected to the channel and is configured for receiving a fixing element for attaching the cooling element to the electric device and/or to an external fixing structure.

19. The cooling element of claim 1, further comprising:
at least one power semiconductor device attached to the second surface of the second plate.

20. The cooling element of claim 12, further comprising:
at least a first power semiconductor device attached to the second surface of the second plate, and
at least a second power semiconductor device attached to the second surface of the third plate.

21. The cooling element of claim 20, wherein the first power semiconductor device is attached to the second plate by a first soldered bond or a first sintered bond, and/or
wherein the second power semiconductor device is attached to the third plate by a second soldered bond or a second sintered bond.

22. The cooling element of claim 19, wherein each power semiconductor device of the at least one power semiconductor device is provided in a respective TO-247 semiconductor package.

23. A cooling element for cooling of an electric device, comprising:
a plate having a first surface and a first structure formed thereon;
a foil having a first surface and a second surface opposite to the first surface, configured to be attached to the electric device at the second surface;
the plate and the foil are attached to one another facing their respective first surface such that the first structure is arranged between the plate and the foil such that a channel is formed between the plate and the foil, wherein the channel is defined by the first structure; and
two liquid connectors at the plate and in liquid communication with the channel for connecting the channel to a cooling circuit.

24. A method for manufacturing a cooling element for cooling of an electrical device, comprising the steps of:
providing a plate having a first surface and a second surface opposite to the first surface and comprising a first structure extending from the first surface, the first structure comprising a periodic arrangement of a basic cell structure, each basic cell structure including at least a cavity surrounded by walls, such that a plurality of cavities separated by intermediate walls are formed at the first surface,
selectively removing at least one intermediate wall, such that neighboring cavities of the plurality of cavities are connected and form a flow path,
providing a cover element having a first surface and a second surface opposite to the first surface,
attaching the cover element to the plate such that their respective first surfaces are facing each other and the first structure is arranged between the plate and the cover element, and such that the flow path forms a channel configured to be streamed through by a cooling liquid, and
providing at least two connectors in liquid communication with the channel for connecting the channel to a cooling circuit.

25. A cooling element for cooling of at least two power semiconductor devices, comprising:
a first plate configured to be attached to a first power semiconductor device;
a second plate configured to be attached to a second power semiconductor device;
an intermediate element comprising at least a frame and at least a liquid-guiding structure;
a liquid inlet arranged in the frame; and
a liquid outlet arranged in the frame,
wherein the first plate is attached to a first side of the intermediate element and the second plate is attached to a second side of the intermediate element such that a cavity is formed between the first plate, the second plate and the frame, wherein the liquid-guiding structure is arranged in the cavity and forms a channel that is in liquid communication with the liquid inlet and the liquid outlet, such that a cooling liquid can flow through the channel.

26. A method for manufacturing a cooling element for cooling of an electric device, comprising the steps of:
providing a first plate having a first surface,
providing a second plate having a first surface and a second surface opposite to the first surface, wherein the second surface is configured to be attached to the electric device,
providing a first structure defining a flow path,
joining the first plate and the second plate such that their respective first surfaces are facing each other, wherein the first structure is arranged between the first plate and the second plate such that a channel is formed between the first plate and the second plate and as defined by the flow path, and
providing at least two connectors in liquid communication with the channel for connecting the channel to a cooling circuit.
